(19) United States
(12) Patent Application Publication
(10) Pub. No.: US 2026/0110819 A1
(43) Pub. Date: Apr. 23, 2026

(54) MAPPING APPARATUS AND LOAD PORT APPARATUS

(71) Applicant: TDK CORPORATION, Tokyo (JP)

(72) Inventors: Tatsuhiro KOTSUGAI, Tokyo (JP); Kodai SATO, Tokyo (JP); Tomoshi ABE, Tokyo (JP)

(73) Assignee: TDK CORPORATION, Tokyo (JP)

(21) Appl. No.: 19/265,409

(22) Filed: Jul. 10, 2025

(30) Foreign Application Priority Data
Jul. 11, 2024 (JP) 2024-111669

(51) Int. Cl. G01V 8/20

(52) U.S. Cl. CPC G01V 8/20

(57) ABSTRACT

A mapping apparatus detecting an accommodated state of a detection object having a plate form accommodated in a container, including: a first sensor having a first optical axis extending along an opening of the container, and a second sensor having a second optical axis configured to extend towards a lateral side of the container and cross obliquely to the first optical axis.

This application claims priority to Japanese patent application No.2024-111669 filed on Jul. 11, 2024 which is incorporated herein by reference in its entirety.

### BACKGROUND OF THE INVENTION

The present disclosure relates to a mapping apparatus and a load port apparatus having the mapping apparatus.

In general, a load port apparatus is provided with a mapping apparatus in order to detect an accommodated state of substrates (such as whether the substrates are stacked or not, or arranged with angle or not) (see Patent Document 1). The mapping apparatus disclosed in Patent Document 1 has a transmission type sensor. An optical axis of the sensor extends in a horizontal direction along an opening of a container. When the sensor descends at the inside of the container, light emitted from the sensor is sequentially irradiated on a plurality of substrates accommodated in the container (specifically, the light is irradiated on the ends of the substrates positioned at an opening side of the container). While the light is being irradiated on the substrates, the accommodated state of the substrates accommodated in the container is detected based on the signal output from the sensor.

Further, a several shelves for holding the substrates are provided on both side walls of the container. Usually, one substrate is arranged on one shelf, however, two or more substrates may be stacked on one shelf. In the case that the substrates are not warped, a detected value when the sensor detects that two stacked substrates is different from a detected value when the sensor detects one substrate. This is because that a detection distance when the sensor detects two stacked substrates (a moving distance along a vertical direction of the sensor) is different from a detected distance when the sensor detects one substrate. Therefore, based on the detection values of the sensor, it is possible to detect whether the substrates are stacked or not.

However, in the case that the substrate is warped, it may be difficult to detect whether the substrate is stacked or not. For example, in the case that the amount of warpage of one substrate is equivalent of a sum of the thicknesses of the two substrates, then the detected distance that the sensor detects from one warped substrate is the same as the detected distance that the sensor detects from two stacked substrates (note that, these two substrates are not warped). Hence, the detected value of the sensor when the one substrate is warped is the same as the detected value that the sensor detects when the substates are stacked (note that, the two substrates are not warped). In such case, it is not possible to distinguish whether one substrate is warped, or two substrates are stacked based on the detected values from the sensor. As such, conventionally it was difficult to accurately detect the accommodated state of the substrates when the substrates were warped.

Patent Document 1: JP Patent Application Laid Open No.2011-35384

### BRIEF SUMMARY OF THE INVENTION

A mapping apparatus according to one aspect of the present disclosure detects an accommodated state of a detection object having a plate form accommodated in a container, including: a first sensor comprising a first optical axis extending along an opening of the container, and a second sensor comprising a second optical axis configured to extend towards a lateral side of the container and cross obliquely to the first optical axis.

The mapping apparatus according to one aspect of the present disclosure includes the first sensor having the first optical axis extending along the opening of the container. Therefore, when the first sensor moves along a vertical direction, at a predetermined timing, the first optical axis crosses the end part (hereinafter, “front end”) of the detection object positioned at the opening side of the container. Based on the detected value of the signal output from the first sensor at this point, it is possible to detect whether the detection objects are stacked or not and whether the detection object is warped. However, it is not possible to distinguish whether the detection object(s) is(are) warped or stacked.

Also, the mapping apparatus according to one aspect of the present disclosure includes the second sensor having the second optical axis extending along the lateral side of the container, wherein the first optical axis and the second optical axis are being crossed obliquely. Therefore, when the second sensor moves along the vertical direction, the second optical axis at least crosses the side part of the detection object. Here, in general, the side parts of the detection object are arranged on the shelves provided on the both lateral side of the container, thus the side parts of the detection object are barely warped. Therefore, in the case that one detection object is warped, the detected value of the second sensor (a detected distance L) is the same as the value which corresponds to a thickness (T) of one detection object. Also, in the case that n numbers (n≥2) of the detection objects are stacked, the detected value of the second sensor (a detected distance L′) is the value which corresponds to a sum of the thicknesses of the n numbers of detection objects (n×T). Therefore, L≠L′; thereby, it is possible to distinguish whether the detection object(s) is(are) warped or stacked based on the detected value of the second sensor.

A load port apparatus according to one aspect of the present disclosure including the mapping apparatus, an installation part for installing the container, and a door opening and closing a lid of the container.

### BRIEF DESCRIPTION OF DRAWINGS

FIG. 1 is a schematic view of a load port apparatus having a mapping apparatus according to the first embodiment of the present disclosure.

FIG. 2 is a schematic view of the load port apparatus shown in FIG. 1 when a container is installed to the load port apparatus.

FIG. 3 is a schematic view showing when the mapping apparatus shown in FIG. 2 is inside the container.

FIG. 4 is a schematic view showing when the mapping apparatus shown in FIG. 3 is descending.

FIG. 5 is a cross section which is viewing the container shown in FIG. 2 from the opening side.

FIG. 6 is a cross section viewing the container shown in FIG. 2 from top.

FIG. 7 is an oblique view of the mapping apparatus shown in FIG. 1.

FIG. 8 is an oblique view of a first sensor, a second sensor, and a jig shown in FIG. 7.

FIG. 9 is a schematic view explaining a detection mechanism of the detection object using the first sensor and the second sensor shown in FIG. 7.

FIG. 10A is a schematic view explaining a moving direction of the first sensor shown in FIG. 7.

FIG. 10B is a schematic view explaining a moving direction of the second sensor shown in FIG. 7.

FIG. 11 is a schematic view showing the detection objects accommodated in the container being warped and stacked.

FIG. 12A is a schematic view explaining a detection mechanism when the first sensor and the second sensor detect the stacking state of the detection objects.

FIG. 12B is a schematic view explaining a detection mechanism when the first sensor and the second sensor detect the warped state of the detection object.

FIG. 13 is an oblique view of a mapping apparatus according to the second embodiment of the present disclosure.

FIG. 14 is an oblique view of the first sensor and the second sensor shown in FIG. 13.

FIG. 15 is an oblique view of a modified example of the first sensor shown in FIG. 10A.

### DETAILED DESCRIPTION OF THE INVENTION

In below, the embodiments of the present disclosure are described by referring to the figures. Note that, the figures are schematic and exemplary representations of the present disclosure for better understanding; thus, the appearances, the dimensional ratio, etc., may not be precisely the same as the actual objects. Also, the present disclosure is not limited to the below-described embodiments.

### First Embodiment

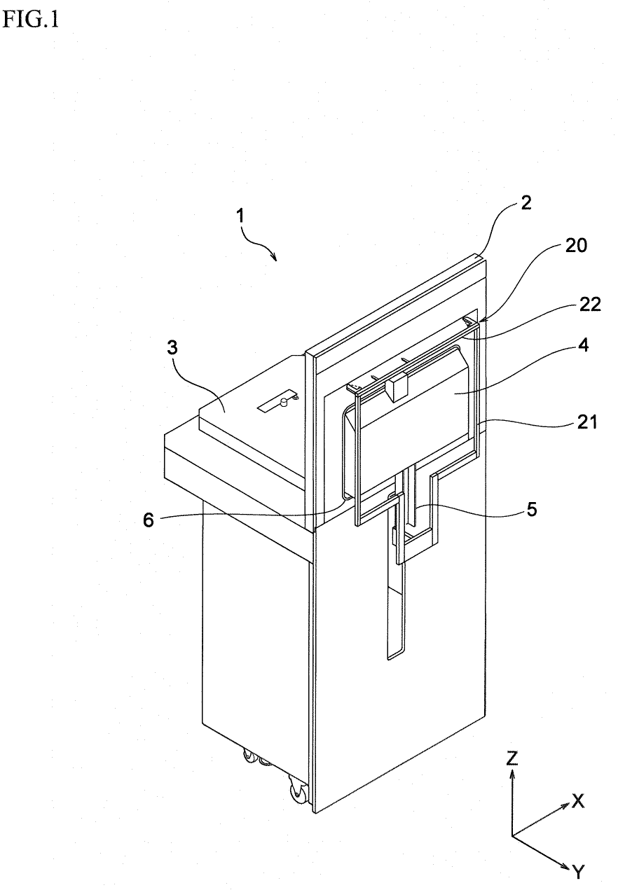

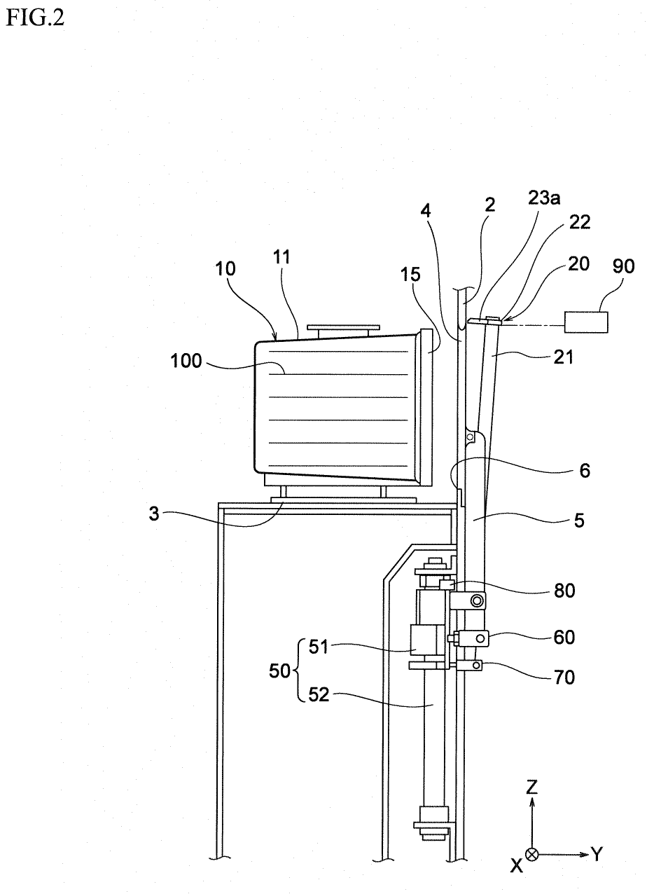

As shown in FIG. 1, a mapping apparatus 20 according to the first embodiment of the present disclosure is provided to a load port apparatus 1. The mapping apparatus 20 is an apparatus which detects an accommodated state of a plurality of detection objects having plate shapes which are accommodated in a container 10 (FIG. 2) (the accommodated state includes whether the detection objects are stacked or not, whether the detection object is warped or not, whether the detection object is arranged while being angled or not, whether the position has shifted or not, and whether the detection objects project to an opening side of the container 10 or not). In the present embodiment, the detection objects of the mapping apparatus 20 are a plurality of substrates 100. The substrate 100 is a square semiconductor wafer (silicon wafer) having a rectangular shape in plan view. Note that, the substrate 100 may be a semiconductor wafer having a circular shape in plan view. Alternatively, the substrate 100 may be a glass substrate having a rectangular shape or a circular shape in plan view.

The load port apparatus 1 is used by being assembled to a semiconductor production apparatus (not shown in the figures) which carries out treatments (such as a heat treatment, a doping treatment which dopes specific impurities, a photolithography treatment, an exposure treatment, and an etching processing) to the substrate 100 (FIG. 2). The load port apparatus 1 is a unit which functions as an interface part between the container 10 and the semiconductor production apparatus.

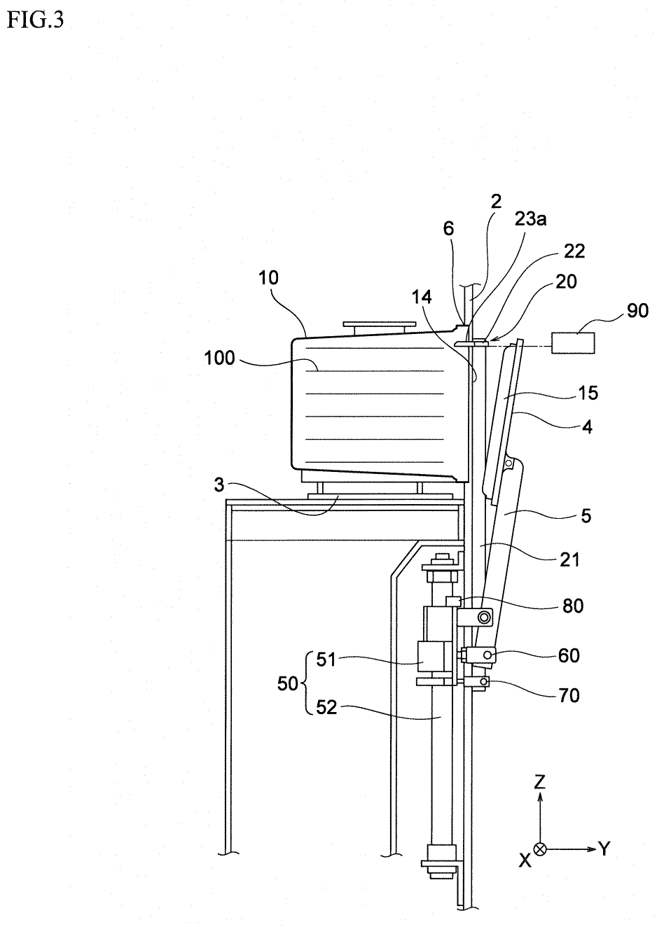

In FIG. 2, FIG. 3, etc., an X-axis is an axis which is parallel to an opening 14 of the container 10 (FIG. 3) among the horizontal directions. Among the horizontal directions, a Y-axis is an axis which is perpendicular to the opening 14 of the container 10. A Z-axis is an axis along a vertical direction. In below, the direction along the Z-axis is a vertical direction, and the direction along the Y-axis direction is a back-and-forward direction. Also, the positive direction along the Z-axis is an upper side, and the negative direction along the Z-axis is a lower side. Further, the negative direction along the Y-axis is a front side, and the positive direction along the Y-axis is a back side.

In the present embodiment, “parallel” does not necessarily mean an exact parallel, and “parallel” in the present embodiment includes a state which is shifted by several degrees (for example, 3°) from the exact parallel. Also, “vertical” is not limited to an exact vertical, and “vertical” in the present embodiment includes a state which is shifted by several degrees (for example, 3°) from the exact vertical.

The container 10 is, for example, FOUP (Front-Opening Unified Pod). The container 10 is used for sealing the plurality of substrates 100 to store and transport them. The container 10 is arranged to an installation part 3 of the load port apparatus 1. For example, the container 10 is transferred to the installation part 3 using an automated transportation device.

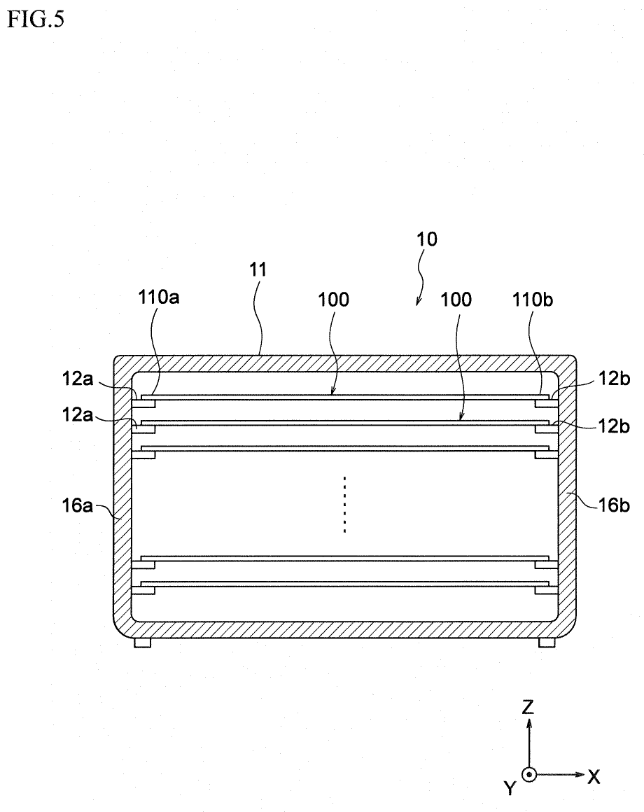

As shown in FIG. 2, the container 10 includes a main body 11 and a lid 15. The plurality of substrates 100 is accommodated inside of the main body 11. The plurality of substrates 100 is arranged on a plurality of shelves along the vertical direction (see FIG. 5). An opening 14 (FIG. 3) is formed at a front surface of the main body 11 (back side). The plurality of substrates 100 moves in and out of the main body 11 through the opening 14 using a robot arm of the semiconductor production device (not shown in the figure).

As shown in FIG. 2 and FIG. 3, the lid 15 is installed to the opening 14 in a removable manner. By installing the lid 15 to the opening 14, the inside of the main body 11 can be sealed, and it is possible to maintain the inside of the container 10 in a highly clean condition.

As shown in FIG. 5, at the inside of the main body 11, a plurality of shelves 12a and a plurality of shelves 12b are provided. The plurality of shelves 12a and the plurality of shelves 12b are arranged by taking a certain space in between each other along the Z-axis. The plurality of shelves 12a and the plurality of shelves 12b extend in the Y-axis direction, and the shelves 12a and the shelves 12b are facing each other in the X-axis direction. The plurality of shelves 12a is installed on a side wall 16a positioned at one side of the main body 11 in the X-axis direction, and the shelves 12a project to the inside from the side wall 16a in the X-axis direction. The plurality of shelves 12b is installed on a side wall 16b positioned at the other side of the main body 11 in the X-axis direction, and the shelves 12b project to the inside from the side wall 16b in the X-axis direction. The plurality of shelves 12a may be provided by taking space from the side wall 16a. Similarly, the plurality of shelves 12b may be provided by taking space from the side wall 16b.

The substrate 100 has a side part 110a positioned at one side in the X-axis direction, and a side part 110b positioned at the other side in the X-axis direction. The side part 110a is placed on the shelf 12a, and the side part 110b is placed on the shelf 12b. The side parts 110a and 110b are respectively supported by the shelves 12a and 12b, but a center part of the substrate 100 in the X-axis direction is not supported.

As shown in FIG. 1 and FIG. 2, the load port apparatus 1 at least includes the mapping apparatus 20. In the present embodiment, the load port apparatus 1 includes a frame 2, the installation part 3, a door 4, a door arm 5, a first driving part 50, a second driving part 60, a third driving part 70, and a sensor position detector 80. Note that, a configuration of the load port apparatus 1 is not limited to the configuration shown in FIG. 1 and FIG. 2, and one or more of the above-mentioned members may be omitted.

The frame 2 is arranged so as to face the front surface (the side where the lid 15 is arranged) of the container 10. The frame 2 has a frame opening 6. The frame opening 6 is provided at a position corresponding to the opening 14, and a dimension of the frame opening 6 corresponds to a dimension of the opening 14. As shown in FIG. 3, when the opening 14 engages with the frame opening 6, the container 10 and the frame 2 are connected. The substrate 100 is taken in and out of the container 10 through the frame opening 6 using the robot arm of the semiconductor production machine (not shown in the figures). The shapes of the frame opening 6 and the opening 14 are not particular limited, and for example, the shapes may be a rectangular shape.

The installation part 3 is a table for installing the container 10, and it can move in a back-and-forward direction. When the installing part 3 moves towards a front side, the container 10 installed on the installation part 3 moves towards the front side. When the installation part 3 moves towards the back side, the container 10 installed on the installation part 3 moves towards the back side.

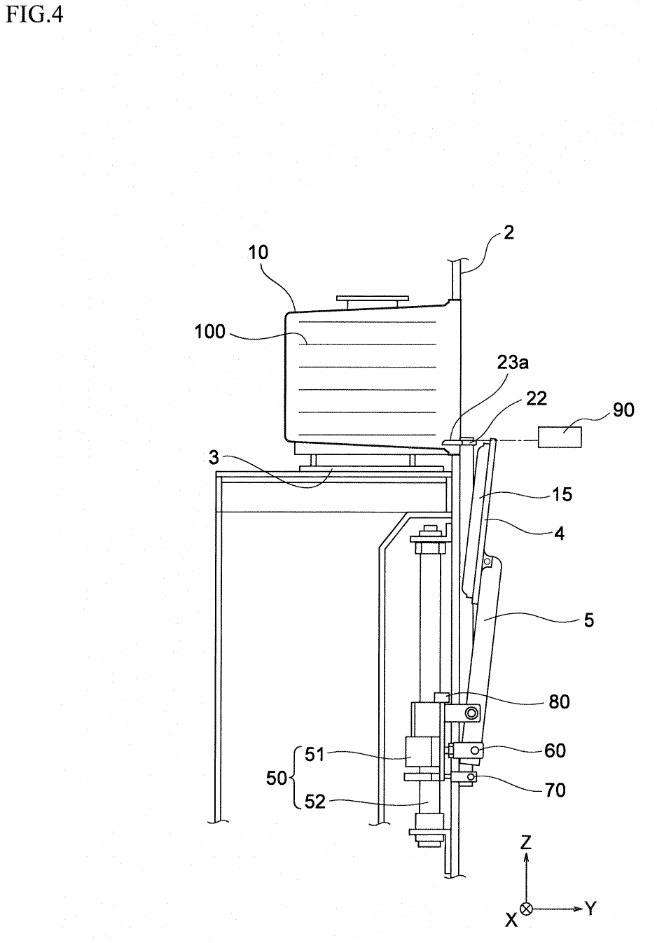

The door 4 moves in a back-and-forward direction in relativity with respect to the frame opening 6; and thereby, the frame opening 6 is opened and closed. Further, the door 4 opens and closes the opening 14 of the container 10 while the door 4 holds the lid 15. When the door 4 moves backwards from the opening 14 while the lid 15 is engaged with the door 4, the lid 15 is removed from the container 10. When the door 4 moves forward towards the opening 14 while the door 4 is engaged with the lid 15, the lid 15 is installed to the container 10. As shown in FIG. 3 and FIG. 4, while the lid 15 is being held, the door 4 moves up and down along the vertical direction with respect to the frame opening 6.

The door arm 5 is fixed to the door 4, and supports the door 4. The door arm 5 is directly and indirectly connected to the first driving part 50. The door arm 5 is configured in a movable manner along a vertical direction. The first driving part 50 is for example a rod less cylinder of an air-driven type, and it includes a movable part 51 and a cylinder tube 52. Compressed air is supplied to and exhausted to the cylinder tube 52. The movable part 51 moves up and down vertically along the cylinder tube 52 by controlling air pressure of the compressed air in the cylinder tube 52.

When the movable part 51 descends along the cylinder tube 52, then the door arm 5 also descends together with the movable part 51. Further, when the movable part 51 ascends along the cylinder tube 52, the door arm 5 ascends together with the movable part 51.

The second driving part 60 enables the door arm 5 to move in a back-and-forward direction, and also enables the door arm 5 to revolve. The door arm 5 revolves around the second driving part 60. As shown in FIG. 2 and FIG. 3, the driving part 60 allows the door arm 5 to revolve towards the back side so as to move away from the frame opening 6. Also, although details are not shown in the figures, the second driving part 60 allows the door arm 5 to revolve towards the front side so as to move closer to the frame opening 6. The second driving part 60 is directly or indirectly connected to the movable part 51. Therefore, the door arm 5 moves up and down together with the second driving part 60 along the vertical movement of the movable part 51.

The third driving part 70 enables a support arm 21 of the mapping apparatus 20 to move in a back-and-forward direction, and enables the support arm 21 to revolve. The support arm 21 revolves around the third driving part 70. As shown in FIG. 2 and FIG. 3, the third driving part 70 allows the support arm 21 to revolve towards the front side (towards the direction approaching the opening 14). Also, although details are not shown in the figures, the third driving part 70 allows the support arm 21 to revolve towards the back side (the direction moving away from the opening 14). The third driving part 70 is directly or indirectly connected to the movable part 51. Therefore, the support arm 21 moves up and down together with the third driving part 70 along the vertical movement of the movable part 51.

The sensor position detector 80 is a position detecting sensor (for example, a transmission type sensor), and it detects the position of the sensor in a vertical direction (i.e., a first sensor 30, a second sensor 40a, a second sensor 40b which are described later) included in the mapping apparatus 20. A signal output from the sensor position detector 80 is provided to a computing part 90 of the mapping apparatus 20. The computing part 90 determines a relative position along the vertical direction of a mapping device with respect to the substrate 100 based on the signal output from the sensor position detector 80.

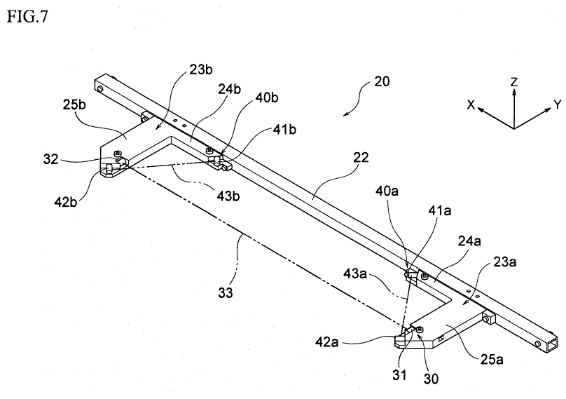

As shown in FIG. 1, the mapping apparatus 20 is provided near the door 4 of the load port apparatus 1. The mapping apparatus 20 detects the accommodated state of the substrate 100 accommodated in the container 10 (FIG. 2). The mapping apparatus 20 includes the support arm 21, the mapping arm 22, the jigs 23a and 23b (FIG. 7), the first sensor 30 (FIG. 7), the second sensors 40a and 40b (FIG. 7), and the computing part 90 (FIG. 2).

As shown in FIG. 1, the support arm 21 is configured of a rod-shaped member. The support arm 21 is arranged along the outer circumference of the door 4 and the door arm 5 so as to surround the door 4 and the door arm 5. The mapping arm 22 is configured of a rod-shaped member, and it is installed to the support arm 21. The mapping arm 22 is joined to the support arm 21 using a joining member such as bolts. Note that, the mapping arm 22 may be formed integrally with the support arm 21.

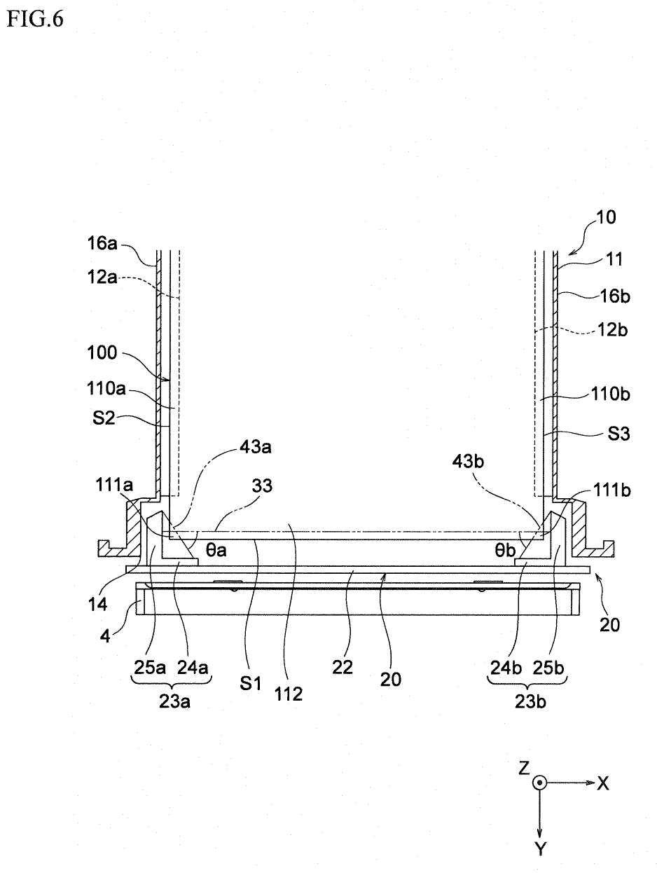

As shown in FIG. 6, the mapping arm 22 is parallel to a horizontal plane, and also parallel to the opening 14 (i.e., parallel to the X-axis). Note that, the mapping arm 22 may be angled by less than 5 degrees with respect to a horizontal plane. Also, the mapping arm 22 may be angled by less than 5 degrees in a horizontal direction with respect to the X-axis. As shown in FIG. 7, a transverse cross section shape of the mapping arm 22 is not particularly limited, and for example, it may a rectangular shape. The mapping arm 22 moves in a back-and-forward direction and in a vertical direction along with the movement of the support arm 21 (FIG. 1) in back-and-forward direction and a vertical direction.

The jigs 23a and 23b are configured of plate-shaped members which are bent in a L-shape. The jigs 23a and 23b are installed to the mapping arm 22, and these are spaced apart from the mapping arm 22 along the axial direction. The jig 23a is positioned at one end in the axial direction of the mapping arm 22, and the jig 23b is positioned at the other end in the axial direction of the mapping arm 22. The jig 23a has a mirror image symmetrical shape with respect to the jig 23b.

The jig 23a includes a first portion 24a and a second portion 25a, and the jig 23b includes a first portion 24b and a second portion 25b. The first portions 24a and 24b extend parallel to the mapping arm 22. The first portions 24a and 24b are installed on the mapping arm 22 using a joining member such as a bolt. The second portions 25a and 25b are respectively continuous with the first portions 24a and 24b, and the second portions 25a and 25b are perpendicular to the first portions 24a and 24b. The angle formed between the first portion 24a and the second portion 25a is 90 degrees; however, the angle may be less than 90 degrees or may be larger than 90 degrees. Similarly, the angle formed between the first portion 24b and the second portion 25b is 90 degrees; however, the angle may be less than 90 degrees or may be larger than 90 degrees.

As shown in FIG. 6, the second portions 25a and 25b extend towards the front side so as to project to the opening 14. Along with the movement of the mapping arm 22 towards the front side, at least part (tip part) of the second portion 25a enters inside the container 10 through the opening 14. More specifically, at least part of the second portion 25a enters between the side part 110a of the substrate 100 and a side wall 16a of the container 10.

Also, along with descending of the mapping arm 22, at least part (tip part) of the second portion 25b enters inside the container 10 through the opening 14. More specifically, the second portion 25b enters between the side part 110b of the substrate 100 and the side wall 16b of the container 10.

When the second portion 25a is arranged at the lateral side of the side part 110a, and the second portion 25b is arranged at the lateral side of the side part 110b, an end part of the substrate 100 at the opening 14 side (hereinafter, this end part is referred to as a front end 112) of the substrate 100 is placed between the second portion 25a and the second portion 25b.

The first portions 24a and 24b are arranged parallel to the opening 14, and the second portions 25a and 25b are arranged perpendicular to the opening 14. The second portions 25a and 25b extend along the Y-axis, and the second portions 25a and 25b may be angled towards the lateral side of the container 10 by less than 10 degrees with respect to the Y-axis.

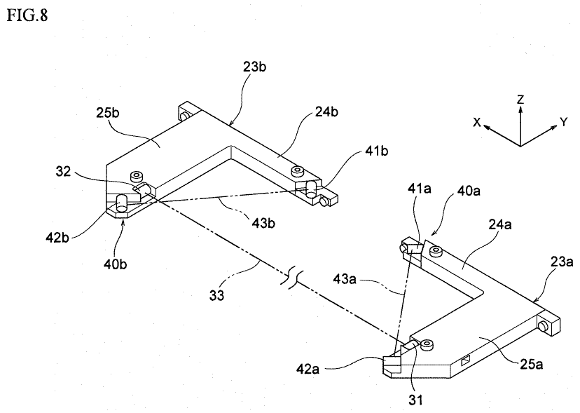

As shown in FIG. 8, the first sensor 30 is an optical sensor (a transmission type sensor), and it detects the front end 112 of the substrate 100 (FIG. 6). The first sensor 30 includes a first light emitting part 31, and a first light reception part 32 receiving the light emitted from the first light emitting part 31. The first light emitting part 31 is, for example, a visible light LED, an infrared LED, an ultraviolet LED, or a laser diode. The first light reception part 32 is, for example, a photoresistor, a photodiode, and an infrared ray detection element.

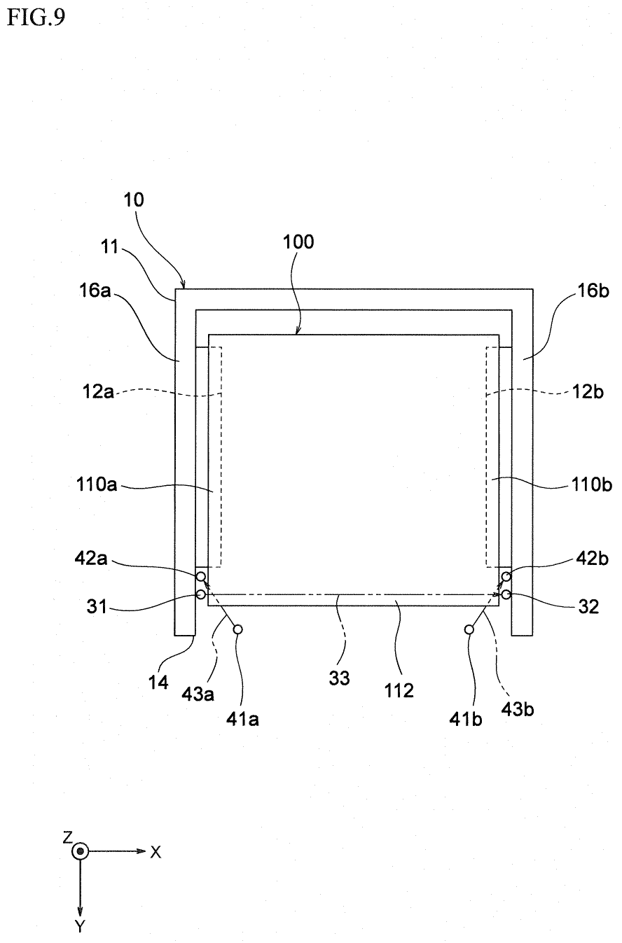

The first light emitting part 31 is facing the first light reception part 32 along the X-axis. The first sensor 30 includes a first optical axis 33 extending along the opening 14 of the container 10 (FIG. 6). The first optical axis 33 is an optical axis of the light which is emitted from the first light emitting part 31. In FIG. 9, etc., for easier understanding, the first optical axis 33 is shown as a hypothetical straight line connecting the first light emitting part 31 and the first light reception part 32; and in the figure, the first optical axis 33 crosses the substrate 100 (passes through the substrate 100). In reality, the light emitted from the first light emitting part 31 does not pass through the substrate 100, and the light is blocked by the substrate 100. As shown in FIG. 8, the first light emitting part 31 is provided to the jig 23a, and the first light reception part 32 is provided to the jig 23b. Note that, the first light emitting part 31 may be provided to the jig 23b, and the first light reception part 32 may be provided to the jig 23a.

The first light emitting part 31 is provided to the end part (tip) in the Y-axis direction of the second portion 25a. The first light reception part 32 is provided to the end part (tip) in the Y-axis direction of the second portion 25b. The first light emitting part 31 and the first light reception part 32 are respectively arranged to the second portions 25a and 25b so that the first optical axis 33 is parallel to the mapping arm 22 (FIG. 6) or the opening 14.

The second sensor 40a is an optical sensor (a transmission type sensor); and the second sensor 40a includes a first light emitting part 41a, and a second light reception part 42a receiving the light emitted from the second light emitting part 41a. The second light emitting part 41a is, for example, a visible light LED, an infrared LED, an ultraviolet LED, and a laser diode. The second light reception part 42a is, for example, a photoresistor, a photodiode, and an infrared ray detection element. The second optical axis 43a is an optical axis of the light which is emitted from the second light emitting part 41a. In FIG. 9, etc., for easier understanding, the second optical axis 43a is shown as a hypothetical straight line connecting the second light emitting part 41a and the second light reception part 42a, and in the figure, the second optical axis 43a crosses the substrate 100 (passes through the substrate 100). In reality, the light emitted from the second light emitting part 41a does not pass through the substrate 100, and the light is blocked by the substrate 100.

As shown in FIG. 8, the second light emitting part 41a is provided to the end part (tip) in the X-axis direction of the first portion 24a. The second light reception part 42a is provided to the end part (tip) in the Y-axis direction of the second portion 25a. Note that, the second light emitting part 41a may be provided to the tip of the second portion 25a, and the second light reception part 42a may be provided to the tip of the first portion 24a. As shown in FIG. 9, the second light reception part 42a is positioned closer to the rear side (the Y-axis negative direction) of the container 10 than the first sensor 30 (the first light emitting part 31). The second light emitting part 41a is positioned closer to the front side of the container 10 (the Y-axis positive direction) than the first sensor 30 (the first light emitting part 31).

As shown in FIG. 8, the second sensor 40b is a transmission type sensor, and it includes a second light emitting part 41b, and a second light reception part 42b receiving the light emitted from the second light emitting part 41b. The second light emitting part 41b is, for example, a visible light LED, an infrared LED, an ultraviolet LED, and a laser diode. The second light reception part 42b is, for example, a photoresistor, a photodiode, and an infrared ray detection element. The second optical axis 43b is an optical axis of the light which is emitted from the second light emitting part 41b. In FIG. 9, etc., for easier understanding, the second optical axis 43b is shown as a hypothetical straight line connecting the second light emitting part 41b and the second light reception part 42b; and in the figure, the second optical axis 43b crosses the substrate 100 (passes through the substrate 100). In reality, the light emitted from the second light emitting part 41b does not pass through the substrate 100, and the light is blocked by the substrate 100.

As shown in FIG. 8, the second light emitting part 41b is provided to the end part (tip) in the X-axis direction of the first portion 24b. The second light reception part 42b is provided to the end part (tip) in the Y-axis direction of the second portion 25b. Note that, the second light emitting part 41b may be provided to the tip of the second portion 25b, and the second light reception part 42b may be provided to the tip of the first portion 24b. As shown in FIG. 9, the second light reception part 42b is positioned closer to the rear side (the Y-axis negative direction side) of the container 10 than the first sensor 30 (the first light reception part 32). The second light emitting part 41b is positioned closer to the front side of the container 10 (the Y-axis positive direction side) than the first sensor 30 (the first light reception part 32).

As shown in FIG. 6, the second light optical axis 43a extends towards the lateral side of the container 10 so that the second light optical axis 43a and the first optical axis 33 are crossed obliquely. When viewing the container 10 from the front side of the container 10 (from the opening 14 side), the second optical axis 43a is angled so that it approaches the side wall 16a towards the rear side of the container 10. The second optical axis 43a is angled towards the side part 110a of the substrate 100, and the second optical axis 43a hypothetically crosses the side part 110a. An angle θa of the second optical axis 43a with respect to the first optical axis 33 is not particularly limited, and it may be 30°≤θa≤60°.

Similarly, the second optical axis 43b extends towards the lateral side of the container 10 so that the second optical axis 43b and the first optical axis 33 are crossed obliquely. When viewing the container 10 from the front side of the container 10, the second optical axis 43b is angled such that it approaches the side wall 16b towards the rear side of the container 10. Therefore, the second optical axis 43b is angled towards the side part 110b of the substrate 100, and the second optical axis 43b hypothetically crosses the side part 110b. An angle Ob of the second optical axis 43b with respect to the first optical axis 33 is not particularly limited, and it may be 30≤<θb≤60°. The angle θb may be the same or different from the angle θa.

During the detection of the substrate 100, at a corner part 111a of the substrate 100, the second optical axis 43a crosses a first side S1 of the substrate 100 which is parallel to the opening 14, and also the second optical axis 43a crosses a second side S2 which is perpendicular to the first side S1. More specifically, the second optical axis 43a obliquely crosses the end part in the X-axis negative direction of the first side S1, and also the second optical axis 43a obliquely crosses the end part in the Y-axis positive direction of the second side S2.

Here, the end part of the first side S1 in the X-axis negative direction refers to a part positioned within a range of 25% of a length of the first side S1 along the X-axis from an intersection point between the first side S1 and the second side S2 (preferably, within 10%, more preferably within 5%, or even more preferably within 3%). Also, the end part of the second side S2 in the Y-axis positive direction refers to a part positioned within a range of 25% of a length of the second side S2 along the Y-axis from an intersection point between the first side S1 and the second side S2 (preferably, within 10%, more preferably within 5%, or even more preferably within 3%). Note that, the corner part 111a of the substrate 100 refers to a range within a predetermined length from the intersection point between the first side S1 and the second side S2. Also, the predetermined length refers to a length of the end part of the first side S1 in the X-axis negative direction which is mentioned in above, or the end part of the second side S2 in the Y-axis positive direction which is also mentioned in above.

During the detection of the substrate 100, at the corner part 111b of the substrate 100, the second optical axis 43b crosses the first side S1 of the substrate 100 which is parallel to the opening 14, and also the second optical axis 43b crosses a third side S3 which is perpendicular to the first side S1. More specifically, the second optical axis 43b obliquely crosses the end part in the X-axis positive direction of the first side S1, and also the second optical axis 43b crosses the end part in the Y-axis positive direction of the third side S3.

Here, the end part in the X-axis positive direction of the first side S1 refers to a part positioned within a range of 25% of a length of the first side S1 along the X-axis from an intersection point between the first side S1 and the third side S3 (preferably, within 10%, more preferably within 5%, or even more preferably within 3%). Also, the end part in the Y-axis positive direction of the third side S3 refers to a part positioned within a range of 25% of a length of the third side S3 along the Y-axis from an intersection point between the first side S1 and the third side S3 (preferably, within 10%, more preferably within 5%, or even more preferably within 3%). Also, the corner part 111b of the substrate 100 refers to a range within a predetermined length from the intersection point between the first side S1 and the third side S3. Note that, the predetermined length refers to a length of the end part in the X-axis positive direction of the first side S1 which is mentioned in above, or the end part in the Y-axis positive direction of the third side S3 which is also mentioned in above.

The second optical axis 43a and the second optical axis 43b distance away from each other towards the rear side of the container 10 (the direction away from the opening 14 toward the front side). The hypothetical extension line of the second optical axis 43a obliquely crosses the side wall 16a of the container 10, and also obliquely crosses the opening 14 (opening plane). Also, the hypothetical extension line of the second optical axis 43b obliquely crosses the side wall 16b of the container 10, and also obliquely crosses the opening 14 (opening plane).

As shown in FIG. 7, height positions of the first light emitting part 31 and the first light reception part 32 from a standard position (for example, a bottom of the container 10 shown in FIG. 5) are at the same height positions of the second light emitting part 41a and the second light reception part 42a from the standard position. Note that, the height positions between these may have a difference of ±7% or less (preferably ±5% or less, or more preferably ±3% or less). Also, height positions of the first light emitting part 31 and the first light reception part 32 from a standard position (for example, the bottom of the container 10 shown in FIG. 5) are at the same height positions of the second light emitting part 41b and the second light reception part 42b from the standard position. Note that, the height positions between these may have a difference of ±7% or less (preferably ±5% or less, or more preferably ±3% or less).

Also, the first light emitting part 31 and the first light reception part 32 are positioned on the same plane where the second light emitting part 41a and the second light reception part 42a are positioned. Therefore, the first optical axis 33 and the second optical axis 43a are positioned on the same plane. Also, the first light emitting part 31 and the first light reception part 32 are positioned on the same plane where the second light emitting part 41b and the second light reception part 42b are positioned. Therefore, the first optical axis 33 and the second optical axis 43b are positioned on the same plane.

The computing part 90 shown in FIG. 2 determines the accommodated state of the substrate 100 accommodated in the container 10 based on a signal output from the sensor position detector 80, a signal output from the first sensor 30 shown in FIG. 7, and a signal output from the second sensors 40a and 40b shown in FIG. 7.

Next, a mechanism for detecting the accommodated state of the substrate 100 using the mapping apparatus 20 is described. As shown in FIG. 3, while the lid 15 is engaged with the door 4 and when the door arm 5 revolves towards the back side, the lid 15 is removed from the container 10. Thereby, the opening 14 of the container 10 is exposed. While under this condition, when the support arm 21 of the mapping apparatus 20 revolves towards the front side, the mapping arm 22 moves forward. As shown in FIG. 6, the second portion 25a and the second portion 25b enter inside the container 10 through the opening 14.

The second portion 25a and the second portion 25b enter inside the container 10, as shown in FIG. 4, the mapping arm 22 descends together with the door arm 5. Also, the mapping apparatus 20 shown in FIG. 7 (the first sensor 30, the second sensor 40a, and the second sensor 40b) detects the accommodated state of the plurality of substrates 100 accommodated in the container 10.

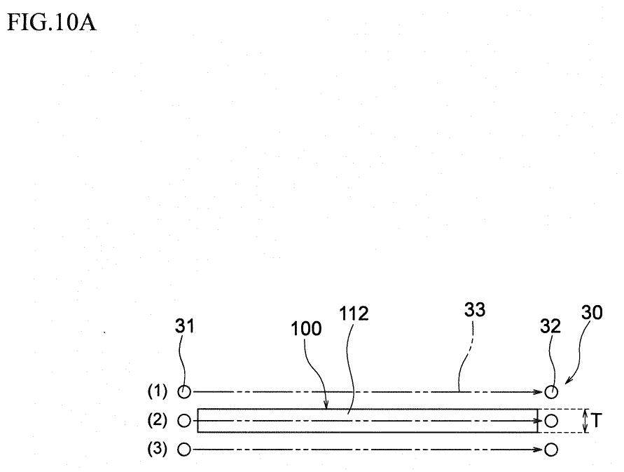

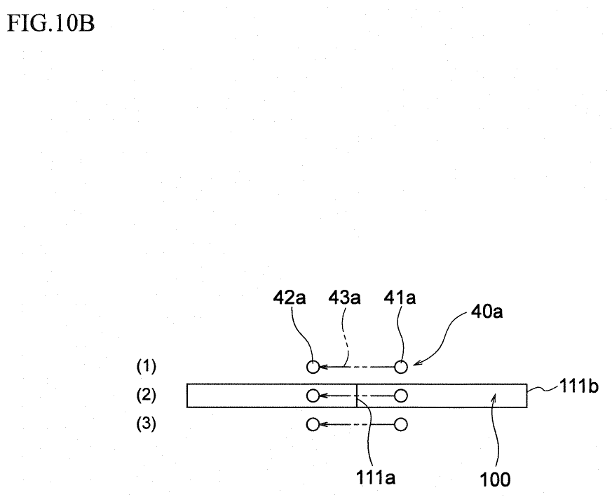

FIG. 10A is a figure viewing one of the plurality of substrates 100 accommodated in the container 10 from the front end 112 side. Along with the descending of the mapping arm 22, the first optical axis 33 of the first sensor 30 descends from the upper position (1) to the lower position (3) of one of the plurality of substrates 100 accommodated in the container 10. At the position (1), the front end 112 is not positioned between the first light emitting part 31 and the first light reception part 32. Therefore, the light emitted from the first light emitting part 31 reaches the first light reception part 32 without being blocked by the front end 112. Thereby, the first light reception part 32 receives the light which is stronger than a predetermined threshold.

Also, at the position (3), the front end 112 is not positioned between the first light emitting part 31 and the first light reception part 32. Therefore, the light emitted from the first light emitting part 31 can reach the first light reception part 32 without being blocked by the front end 112. Thereby, the first light reception part 32 receives the light which is stronger than the predetermined threshold.

Further, at the position (2), the front end 112 is positioned between the first light emitting part 31 and the first light reception part 32. Therefore, the light emitted from the first light emitting part 31 is blocked by the front end 112. Therefore, the first light reception part 32 receives the light weaker than the predetermined threshold. Therefore, the light amount that the first light reception part 32 receives changes depending on the presence of the substrate 100 between the first light emitting part 31 and the first light reception part 32. Thus, a detected value of the signal output from the first sensor 30 is a value which corresponds to the light amount that the first light reception part 32 receives; and, the detected value changes depending on the presence of the substrate 100 (the front end 112) between the first light emitting part 31 and the first light reception part 32. As described later, the light amount that the first light reception part 32 receives changes depending on the accommodated state of the substrate(s) 100 in the container 10 (i.e., whether the substrates are stacked or not, whether the substrate is warped or not, and whether the substrate is obliquely arranged or not).

FIG. 10B is a figure showing one of the plurality of substrates 100 accommodated in the container 10 viewing from the corner part 111a side. In below, among the second sensors 40a and 40b, the detection mechanism of the substrate 100 by the second sensor 40a is described. Detailed description of the detection mechanism of the substrate 100 by the second sensor 40b is not described, since it is the same as the detection mechanism of the substrate 100 by the second sensor 40a.

As the mapping arm 22 descends, the second optical axis 43a of the second sensor 40a descends to the lower position (3) from the upper position (1) of one of the substrates 100 accommodated in the container 10. At the position (1), the corner part 111a is not positioned between the second light emitting part 41a and the second light reception part 42a. Therefore, the light emitted from the second light emitting part 41a reaches the second light reception part 42a without being blocked by the corner part 111a. Thereby, the second light reception part 42a receives the light stronger than the predetermined threshold.

Also, at the position (3), the corner part 11la is not positioned between the second light emitting part 41a and the second light reception part 42a. Thus, the light emitted from the second light emitting part 41a reaches the second light reception part 42a without being blocked by the corner part 111a. Thereby, the second light reception art 42a receives the light stronger than the predetermined threshold.

Further, at the position (2), the corner part 111a is positioned between the second light emitting part 41a and the second light reception part 42a. Therefore, the light emitted from the second light emitting part 41a is blocked by the corner part 111a. Thereby, the second light reception part 42a receives the light weaker than the predetermined threshold. Therefore, the light amount that the second light reception part 42a receives changes depending on the presence of the substrate 100 between the second light emitting part 41a and the second light reception part 42a. Therefore, the detected value of the signal output from the second sensor 40a is a value corresponding to the light amount that the second light reception part 42a receives. Hence, the detected value of the signal changes depending on the presence of the substrate 100 (the corner part 111a) between the second light emitting part 41a and the second light reception part 42a. As described later, the light amount that the second light reception part 42a receives changes depending on the accommodated condition of the substrate 100 in the container 10 (i.e., whether the substrates are stacked or not, the substrate is warped or not, and whether the substrate is obliquely arranged or not).

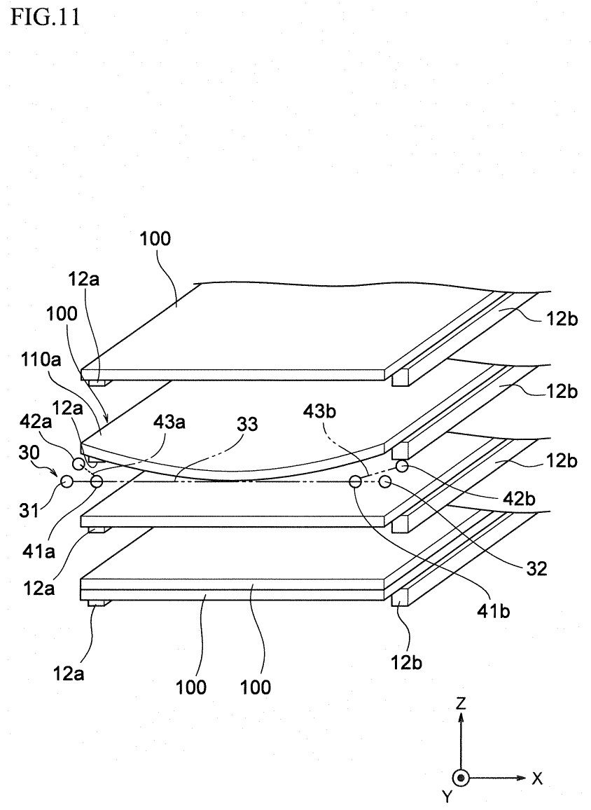

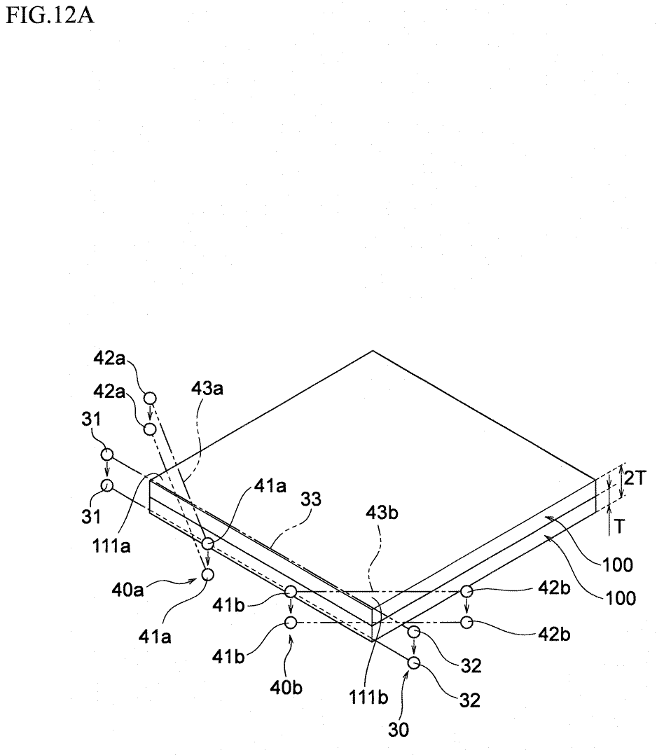

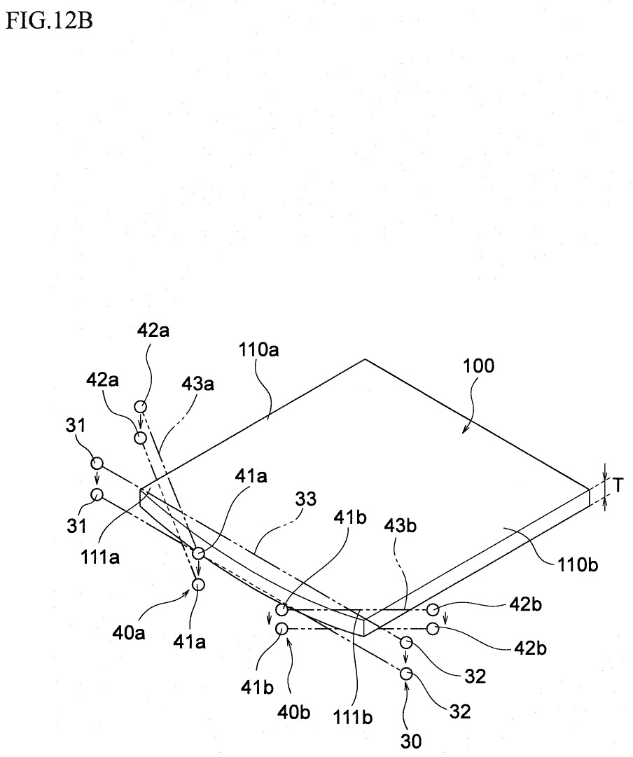

Here, as shown in FIG. 11, two substrates 100 may be accidentally stacked and arranged between the first shelves 12a and 12b. As shown in FIG. 12A, when the first sensor 30 detects the two substrates 100, the light emitted from the first light emitting part 31 is blocked by the front end 112 of the two substrates 100. In other words, the first optical axis 33 crosses the front end 112. During this time, the first sensor 30 descends the distance which is equivalent of double the thickness T of one substrate 100. Therefore, when the first sensor 30 detects the two stacked substrates 100, the detected value of the signal output from the first sensor 30 is a value which corresponds to double the thickness T of one substrate 100 (a sum of the thicknesses of two substrates 100:2T).

Further, as explained using FIG. 10A, when the first sensor 30 detects one substrate 100, the light emitted from the first light emitting part 31 is blocked by the front end 112 of one substrate 100. During this time, the first sensor 30 descends the distance which corresponds to a thickness T of one substrate 100. Therefore, when the first sensor 30 detects one substrate 100, the detected value of the signal output from the first sensor 30 is a value which corresponds to a thickness T of one substrate 100.

As such, in the case that the substrate 100 is not warped, the detected distance (moved distance) when the first sensor 30 detects two stacked substrates 100 is double the detected distance when the first sensor 30 detects only one substrate 100. Therefore, the detected value by the first sensor 30 when the first sensor 30 detects the two stacked substrates is different from the detected value by the first sensor 30 when the first sensor 30 detects only one substrate 100. Therefore, based on the detected value by the first sensor 30, the accommodated state of the substrates 100 (here, the accommodated state refers to whether the substrates 100 are stacked or not) can be determined.

However, as shown in FIG. 11, when the substrate 100 is warped (particularly when the center of the substrate 100 is warped), it is difficult to distinguish whether the substrate(s) 100 is(are) stacked or warped only by using the first sensor 30. In the case that the amount of warpage of one substrate 100 is equivalent of a sum of the thicknesses (2T) of two substrates 100, the detected value upon detecting one warped substrate 100 using the first sensor 30 is a value which corresponds to the sum of the thicknesses (2T) of the two substrates 100. Further, as mentioned in above, when the first sensor 30 detects the two stacked substrates 100, the detected value of the first sensor 30 is a value which corresponds to the sum of the thicknesses (2T) of the two substrates 100.

Therefore, theoretically, the detected value when the first sensor 30 detects one warped substrate 100 is the same as the detected value by the first sensor 30 when the first sensor 30 detects the two stacked substrates 100. In this case, it is not possible to distinguish whether one substrate 100 is warped or the two substrates 100 which are not warped are stacked simply based on the detected value by the first sensor 30.

Here, in order to solve such problems, as shown in FIG. 7, in addition to the first sensor 30, the mapping apparatus 20 is provided with at least one of the second sensors 40a and 40b (in the present embodiment, both sensors are provided). As shown in FIG. 9, the second optical axis 43a of the second sensor 40a extends towards the lateral side of the container 10 such that the second optical axis 43a obliquely crosses the first optical axis 33.

Therefore, as shown in FIG. 12B, when the second sensor 40a detects the substrate 100, the second optical axis 43a crosses the side part 110a of the substrate 100 at the corner part 111a of the substrate 100. During this time, the light emitted from the second light emitting part 41a is blocked by the side part 110a of one substrate 100 which is warped. Here, in general, it is difficult for the side part 110a to warp since it is arranged on the shelf 12a (FIG. 5). Therefore, while the second optical axis 43a and the side part 110a of the warped substrate 100 are crossed, the second sensor 40a descends the distance which is equivalent to the thickness T of the substrate 100. Hence, when the second sensor 40a detects one warped substrate 100, the detected value of the signal output from the second sensor 40a is a value corresponding to the thickness T of the substrate 100.

Also, as shown in FIG. 12A, when the second sensor 40a detects the two stacked substrates 100, the second optical axis 43a and the side parts 110a of the two stacked substrates 100 are crossed at the corner parts 111a of the two stacked substrates 100. Here, the light emitted from the second light emitting part 41a is blocked by the side parts 110a of the two stacked substrates 100. As mentioned in above, in general, the side part 110a is unlikely to warp as it is arranged on the shelf 12a (FIG. 5). Therefore, while the second optical axis 43a and the side parts 110a of the two stacked substrates 100 are crossed, the second sensor 40a descends the distance corresponding to a sum of the thicknesses (2T) of the two substrates 100. Therefore, when the second sensor 40a detects the two stacked substrates 100, the detected value of the signal output from the second sensor 40a is a value which corresponds to the sum of the thicknesses (2T) of the two substrates 100.

As a result, the detected value that the second sensor 40a detects one warped substrate 100 (the value corresponding to a thickness T of the substrate 100) is different from the detected value when the second sensor 40a detects two stacked substrates 100 (the value corresponding to the sum of the thicknesses 2T of the two stacked substrates 100). Thereby, it is possible to distinguish whether the substrate(s) 100 is(are) warped or stacked based on the detected value of the second sensor 40a.

As discussed in above, the mapping apparatus 20 of the present embodiment can accurately detect the accommodated state of the substrate(s) 100 (stacked or not, warped or not, etc), regardless of whether the substrate 100 is warped or not. Also, the mapping apparatus 20 of the present embodiment can also detect whether the substrate 100 is tilted or not, whether the position is shifted or not, whether the substrate 100 projects towards the opening side of the container 10 or not, etc.

Also, as shown in FIG. 7, the height positions of the first light emitting part 31 and the light reception part 32 from the standard position (for example, the bottom of the container 10 shown in FIG. 5) are the same as the height positions of the second light emitting part 41a and the second light reception part 42a from the standard position. When the height positions of the first light emitting part 31 and the first light reception part 32 are different from the height positions of the second light emitting part 41a and the second light reception part 42a, the amount of the moving distance which has decreased along the vertical direction of the first sensor 30 and the second sensor 40a is equal to the distance corresponding to the height difference. Further, when the height positions of the first light emitting part 31 and the first light reception part 32 are the same as the height positions of the second light emitting part 41a and the second light reception part 42a, the first sensor 30 and the second sensor 40a can both move from the upper end to the lower end of the container 10 (FIG. 5). Therefore, the first sensor 30 and the second sensor 40a can detect the accommodated state of the substrate(s) 100 in the container 10 in a wider range along the vertical direction.

Also, as shown in FIG. 9, the second light emitting part 41a is positioned towards the front surface side of the container 10 than the first sensor 30; and, the second light reception part 42a is positioned towards the rear side of the container 10 than the first sensor 30. Thus, when the first sensor 30 and the second sensor 40a move along the vertical direction, the second optical axis 43a crosses the side part 110a of the substrate 100 when the first optical axis 33 crosses the front end 112 of the substrate 100. Thereby, the detected value of the first sensor 30 and the detected value of the second sensor 40a are acquired substantially at the same time, and a detection speed of the mapping apparatus 20 improves.

Also, as shown in FIG. 6, the second optical axis 43a and the second optical axis 43b distance away from each other towards the rear side of the container 10. Thus, the second optical axis 43a extends towards the side wall 16a side of the container 10 when viewed from the opening 14. Thus, the second optical axis 43a hypothetically crosses the side part 110a of the substrate 100. Also, the second optical axis 43b extends to the side wall 16b side of the container 10 when viewed from the opening 14. Then, the second optical axis 43b hypothetically crosses the side part 110b of the substrate 100. Thereby, the second sensors 40a and 40b can detect the accommodated state of the substrate 100 based on the detected values of both of the side parts 110a and 110b of the substrate 100. Hence, the second sensor 40a and 40b can accurately detect the accommodated state of the substrate 100.

Also, as shown in FIG. 6 and FIG. 7, the mapping apparatus 20 includes the mapping arm 22 parallel to the opening 14, the jigs 23a and 23b installed to the mapping arm 22 and provided with the first sensor 30, the second sensor 40a, and the second sensor 40b. When the mapping arm 22 moves forward towards the opening 14 of the container 10, the first sensor 30, the second sensor 40a (the second light reception part 42a), and the second sensor 40b (the second light reception part 42b) enter inside the container 10. While in this state, when the mapping arm 22 descends, the first optical axis 33 crosses the front end 112 of the substrate 100, and also the second optical axes 43a and 43b respectively crosses the side parts 110a and 110b of the substrate 100. Thereby, the detected value of the first sensor 30 and the detected values of the second sensors 40a and 40b can be obtained.

Also, in the present embodiment, the movement of the arm to handle the substrate 100 can be stopped depending on the stacked condition of the plurality of substrates 100, or the warped state of the substrate 100. Thereby, it is possible to prevent the interference between the arm and the substrate 100. Also, as shown in FIG. 11, it is possible to confirm a space which allows the arm to safely enter between one of the shelves 12a and 12b and the other one of the shelves 12a and 12b which are adjacent to each other in vertical direction. Thereby, the arm or the substrate 100 can be prevented from breaking.

### Second Embodiment

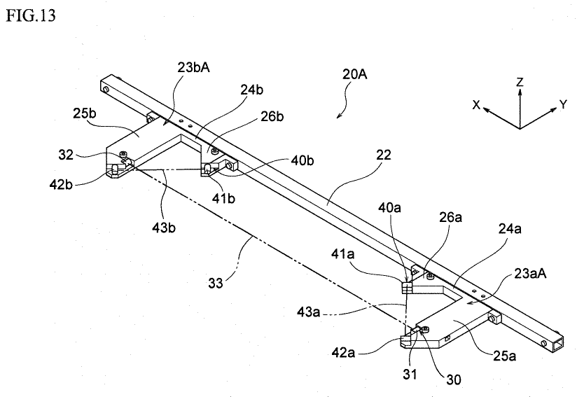

A mapping apparatus 20A of the second embodiment shown in FIG. 13 is basically configured the same as the mapping apparatus 20 according to the first embodiment. The parts which overlap with the mapping apparatus 20 according to the first embodiment are given with the same numerical references, and the detailed explanations of overlapping parts are omitted.

The mapping apparatus 20A is different from the mapping apparatus 20 of the first embodiment since the mapping apparatus 20A includes jigs 23aA and 23bA. The jig 23aA includes a third portion 26a in addition to a first portion 24a and a second portion 25a. The jig 23bA includes a third portion 26b in addition to a first portion 24b and a second portion 25b. The third portions 26a and 26b project out from the first portions 24a and 24b along the Y-axis direction towards a direction away from the mapping arm 22. The projecting direction of the third portions 26a and 26b are respectively the same as the projecting direction of the second portions 25a and 25b.

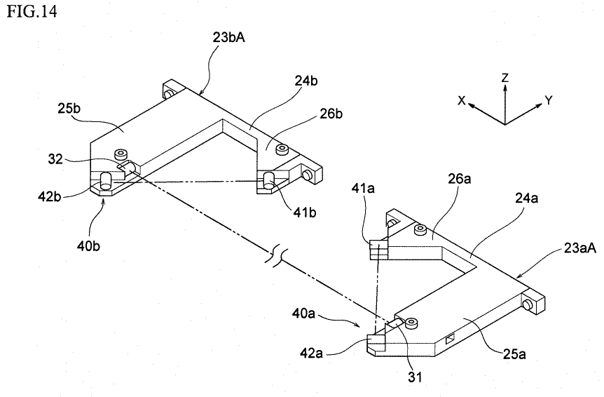

As shown in FIG. 14, the second light emitting part 41a is provided to the third portion 26a. Note that, the second light reception part 42a may be provided to the third portion 26a. Also, the second light emitting part 41b is provided to the third portion 26b. Note that, the second light emitting part 42b may be provided to the third portion 26b.

In the present embodiment, it is possible to achieve the same effects as in the case of the first embodiment. Furthermore, in the present embodiment, the jig 23aA is provided to the third portion 26a, and the third portion 26b is provided to the jig 23bA. Therefore, when the jigs 23aA and 23bA are arranged inside of the container 10 (FIG. 5), it is possible to adjust the position of the light emitting parts 41a and 41b in a back-and-forward direction. Thereby, the detection precision of the second sensors 40a and 40b can be adjusted.

Note that, the present disclosure is not limited to the above-mentioned embodiments, and various modifications are possible within the scope of the present disclosure.

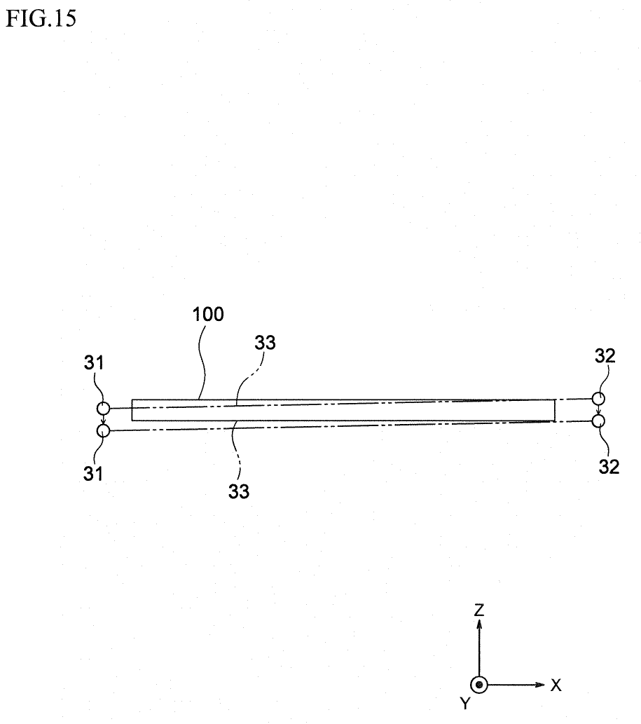

At least one of the first optical axis 33 and the second optical axis 43a (43b) shown in FIG. 7 may be angled with respect to a horizontal plane. For example, as shown in FIG. 15, the first optical axis 33 may be angled with respect to a horizontal plane. Although the detailed figure is not shown, the second optical axis 43a may be angled with respect to a horizontal plane. Also, the second optical axis 43b may be angled with respect to a horizontal plane as well. In this case, according to at least one of the first optical axis 33 and the second optical axis 43a (43b), the detection distance of at least one of the first sensor 30 and the second sensor 40a (40b) increases (the moving distance increases). Thus, for example, it is possible to accurately detect whether the substrates 100 are stacked or not, and whether the substrate 100 is warped or not.

As shown in FIG. 11, the shape of the substrate 100 is a rectangular shape in plan view; however, it may be a circular plane. In this case, the second optical axis 43a crosses the outer circumference of the substrate 100 at arbitrary two points. At least one of these two points is preferably positioned at the lateral side (the side wall 16a side) of the container 10 shown in FIG. 6. That is, the second optical axis 43a preferably crosses at least one point on the outer circumference of the substrate 100 at the lateral side (the side wall 16a side) of the container 10.

Also, the second optical axis 43b crosses arbitrary two points on the outer circumference of the substrate 100. At least one of these two points is preferably positioned at the lateral side of the container 10 (the side wall 16b side). That is, the second optical axis 43b preferably crosses at least one point on the outer circumference of the substrate 100 at the lateral side (the side wall 16b side) of the container 10.

As shown in FIG. 7, the mapping apparatus 20 includes both the second sensor 40a and the second sensor 40b; however, it may be either one of the second sensors 40a and 40b.

The first sensor 30, the second sensor 40a, and the second sensor 40b are optical sensors, however, these may be ultrasound sensors, magnetic sensors, etc.

### DESCRIPTION OF THE REFERENCE NUMERICAL

1 . . . Load port apparatus
2 . . . Frame
3 . . . Installation part
4 . . . Door
5 . . . Door arm
6 . . . Frame opening
10 . . . Container
11 . . . Main body
12a, 12b . . . Shelf
14 . . . Opening
15 . . . Lid
16a, 16b . . . Side wall
20, 20A . . . Mapping apparatus
21 . . . Support arm
22 . . . Mapping arm
23a, 23b, 23aA, 23bA . . . Jig
24a, 24b . . . First portion
25a, 25b . . . Second portion
26a, 26b . . Third portion
30 . . . First sensor
31 . . . First light emitting part
32 . . . First light reception part
33 . . . First optical axis
40a, 40b . . Second sensor
41a, 41b . . . Second light emitting part
42a, 42b . . . Second light reception part
43a, 43b . . . Second optical axis
50 . . . First driving part
51 . . . Movable part
52 . . . Cylinder tube
60 . . . Second driving part
70 . . . Third driving part
80 . . . Sensor position detection part
90 . . . Computing part
100 . . . Substrate
110a, 110b . . . Side part
111a, 111b . . . Corner part
112 . . . Front end

What is claimed is:

1. A mapping apparatus detecting an accommodated state of a detection object having a plate form accommodated in a container, comprising:
a first sensor comprising a first optical axis extending along an opening of the container, and
a second sensor comprising a second optical axis configured to extend towards a lateral side of the container and cross obliquely to the first optical axis.

2. The mapping apparatus according to claim 1, wherein the second optical axis is angled so as to approach closer to a side wall of the container towards a rear side of the container.

3. The mapping apparatus according to claim 1, wherein the detection object has a square shape in plan view;
the detection object comprises a first side parallel to the opening and a second side perpendicular to the first side; and
the second optical axis crosses the first side and the second side at a corner of the detection object.

4. The mapping apparatus according to claim 1, wherein the detection object has a circular shape in plan view;
the second optical axis crosses an outer circumference of the detection object at a first point and a second point on the outer circumference of the detection object; and
at least one of the first point and the second point is positioned at the lateral side of the container.

5. The mapping apparatus according to claim 1, wherein
the first sensor comprises a first light emitting part and a first light reception part receiving a light emitted from the first light emitting part;
the second sensor comprises a second light emitting part and a second light reception part receiving a light emitted from the second light emitting part; and
height positions of the first light emitting part and the first light reception part are the same as height positions of the second light emitting part and the second light reception part

6. The mapping apparatus according to claim 1, wherein the second sensor comprises a second light emitting part and a second light reception part receiving a light emitted from the second light emitting part;
either one of the second light emitting part and the second light reception part is positioned closer to a front side of the container than the first sensor; and
the other one of the second light emitting part and the second light reception part is positioned further towards a rear side of the container than the first sensor.

7. The mapping apparatus according to claim 1, wherein the second sensor comprises a pair of second sensors, the second optical axis of one of the pair of second sensors and the second optical axis of the other one of the pair of second sensors distance away from each other towards a rear side of the container.

8. The mapping apparatus according to claim 1, wherein at least one of the first optical axis and the second optical axis is angled with respect to a horizontal plane.

9. The mapping apparatus according to claim 1 further comprising a mapping arm parallel to the opening, and a jig installed on the mapping arm and provided with the first sensor and the second sensor.

10. A load port apparatus comprising the mapping apparatus according to claim 1, an installation part for installing the container, and a door opening and closing a lid of the container.
